(19) United States
(12) Patent Application Publication
(10) Pub. No.: US 2014/0209161 A1
(43) Pub. Date: Jul. 31, 2014

(54) Nanostructured CIGS Absorber Surface for Enhanced Light Trapping

(71) Applicant: HelioVolt Corporation, Austin, TX (US)

(72) Inventors: Baosheng Sang, Austin, TX (US); Dingyuan Lu, Austin, TX (US); Roy Mark Miller, Austin, TX (US); Casiano R. Martinez, Austin, TX (US); Minsik Kim, Austin, TX (US); Changsup Moon, Austin, TX (US); Billy J. Stanbery, Austin, TX (US)

(73) Assignee: HelioVolt Corporation, Austin, TX (US)

(21) Appl. No.: 13/966,221

(22) Filed: Aug. 13, 2013

Related U.S. Application Data
(60) Provisional application No. 61/682,672, filed on Aug. 13, 2012.

(51) Int. Cl. H01L 31/0236; H01L 31/18

(52) U.S. Cl. CPC H01L 31/02363; H01L 31/1872
USPC 136/256; 438/71

(57) ABSTRACT

A technique includes fabricating a layered precursor including: depositing a first film including a first indium gallium selenide compound on a substrate; then depositing a second film including a CuSe compound; then heating the substrate, the first film and the second film to convert the CuSe compound in the second film to a Cu₂₋ₓSe (0.2=≦x≦1) compound; then reactively depositing a third film including a second indium gallium selenide compound to convert the first film, the second film and the third film into a CIGS absorber film; and forming nanoscale morphological asymmetries in the CIGS absorber film, wherein a surface portion of the CIGS absorber film has a distribution of grain sizes with gaps between most of their surface area characterized by reentrant angles which effectively trap light.

### CROSS-REFERENCE TO RELATED APPLICATION

Referring to the application data sheet filed herewith, this application claims a benefit of priority under 35 U.S.C. 119(e) from copending provisional patent application U.S. Ser. No. 61/682,672, filed Aug. 13, 2012, the entire contents of which are hereby expressly incorporated herein by reference for all purposes.

### BACKGROUND

Despite its remarkably high optical absorption coefficient, conventional CIGS absorbers are characterized by a planar top surface (relative to direction of solar radiation), requiring thicknesses on the order of 1-3μ in order to absorb all of the incident light and achieve high short-circuit current. These conventional planar CIGS absorbers suffer from relatively large dark recombination currents because the bulk of the semiconductor film buried beneath the surface receives relatively little infrared illumination due to shorter wavelength absorption near the planar surface on which the solar spectrum is incident, and because collection of carriers generated deeply within the absorber slab requires transport of minority carriers to the relatively distant planar junction. This reduces their efficiency compared to the potential efficiency of thinner absorber layers with non-planar surfaces that reduce reflection, trap light within the absorber through multiple internal reflections, and reduce the distance minority carriers must travel before crossing the junction where they become majority carriers and their recombination probability is thereby eliminated.

### SUMMARY

There is a need for the following embodiments of the present disclosure. Of course, the present disclosure is not limited to these embodiments.

According to an embodiment of the present disclosure, a method comprises: fabricating a layered precursor including: depositing a first film including a first indium gallium selenide compound on a substrate; then depositing a second film including a CuSe compound; then heating the substrate, the first film and the second film to convert the CuSe compound in the second film to a Cu₂₋ₓSe (0.2=<x<1) compound; then reactively depositing a third film including a second indium gallium selenide compound to convert the first film, the second film and the third film into a CIGS absorber film; and forming nanoscale morphological asymmetries in the CIGS absorber film, wherein a surface portion of the CIGS absorber film has a distribution of grain sizes with gaps between most of their surface area characterized by reentrant angles which effectively trap light. According to another embodiment of the present disclosure, a composition of matter comprises a GIGS absorber film including nanoscale morphological asymmetries in the CIGS absorber film, wherein a surface portion of the GIGS absorber film has a distribution of grain sizes with gaps between most of their surface area characterized by reentrant angles which effectively trap light. According to another embodiment of the present disclosure, an apparatus comprises a GIGS absorber film including nanoscale morphological asymmetries in the GIGS absorber film, wherein a surface portion of the GIGS absorber film has a distribution of grain sizes with gaps between most of their surface area characterized by reentrant angles which effectively trap light.

These, and other, embodiments of the present disclosure will be better appreciated and understood when considered in conjunction with the following description and the accompanying drawings. It should be understood, however, that the following description, while indicating various embodiments of the present disclosure and numerous specific details thereof, is given for the purpose of illustration and does not imply limitation. Many substitutions, modifications, additions and/or rearrangements may be made within the scope of embodiments of the present disclosure, and embodiments of the present disclosure include all such substitutions, modifications, additions and/or rearrangements.

### BRIEF DESCRIPTION OF THE DRAWINGS

The drawings accompanying and forming part of this specification are included to depict certain embodiments of the present disclosure. A clearer concept of the embodiments described in this application will be readily apparent by referring to the exemplary, and therefore nonlimiting, embodiments illustrated in the drawings (wherein identical reference numerals (if they occur in more than one view) designate the same elements). The described embodiments may be better understood by reference to one or more of these drawings in combination with the following description presented herein. It should be noted that the features illustrated in the drawings are not necessarily drawn to scale.

FIG. 1 is an image of a CIGS absorber layer designed for light trapping.

FIGS. 2A-2E are schematic diagrams showing exemplary, sequential steps to fabricate a CIGS absorber layer designed for light trapping.

FIG. 3A, is an image of a plane view of a conventional morphology appropriately labeled “prior art” and FIG. 3B is a cross-sectional image of a CIGS absorber designed for light trapping.

FIG. 4A, is an image of a GIGS absorber designed for light trapping made with a rapid isothermal processor approach and FIG. 4B is an image of a CIGS absorber designed for light trapping made with a rapid optical processor method.

FIGS. 5A-5C are images of a buffer layer conformally coupled to a CIGS absorber layer designed for light trapping.

FIG. 6 illustrates results for quantum efficiency as a function of wavelength (nm) for a GIGS absorber layer designed for light trapping conformally coupled to a buffer layer.

FIGS. 7A-7C are images of a transparent resistive oxide layer coupled to a buffer layer coupled to a GIGS absorber layer that is designed for light trapping. FIGS. 7D-7F are images of a transparent resistive oxide layer coupled to a buffer layer coupled to a GIGS absorber layer designed for light trapping.

### DETAILED DESCRIPTION

Embodiments presented in the present disclosure and the various features and advantageous details thereof are explained more fully with reference to the nonlimiting embodiments that are illustrated in the accompanying drawings and detailed in the following description. Descriptions of well known starting materials, processing techniques, components and equipment are omitted so as not to unnecessarily obscure the embodiments of the present disclosure in detail. It should be understood, however, that the detailed description and the specific examples are given by way of illustration only and not by way of limitation. Various substitutions, modifications, additions and/or rearrangements within the scope of the underlying inventive concept will become apparent to those skilled in the art from this disclosure.

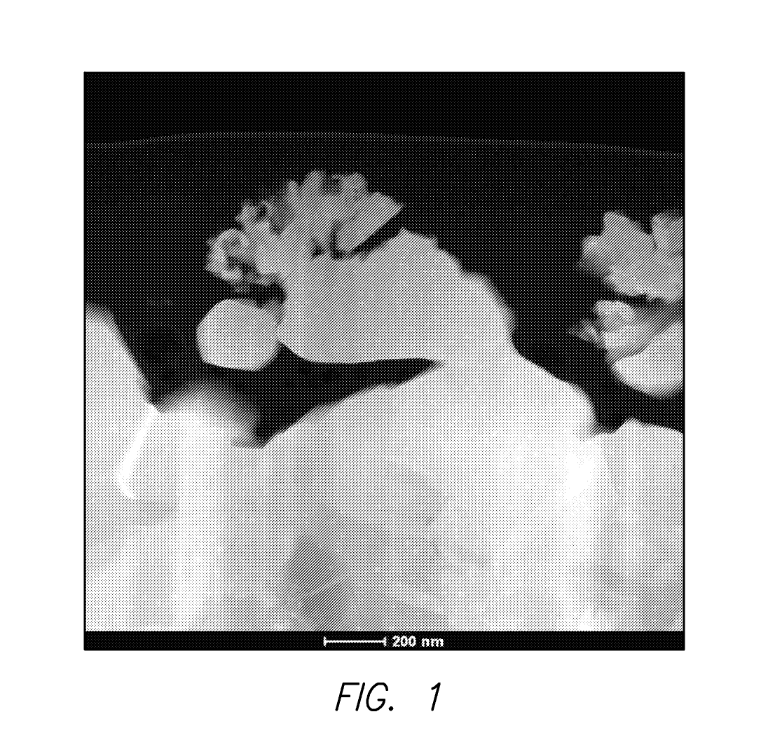

Referring to FIG. 1, embodiments of the present disclosure can include CIGS absorber layers with both substantially non-planar surfaces and high quality bulk and surface electronic properties. Embodiments of the present disclosure can include GIGS absorber films including surface portions having characteristic morphological asymmetries that are created in a final structure by simultaneous processes of Cu—Se flux-assisted re-crystallization characterized by coalescence and coarsening of both the CIGS grains and the voids formed between them by reactive mass transport. Embodiments of the present disclosure can include a high reactive diffusion flux of copper and selenium favoring crystal grain regrowth and coalescence, supporting dendritic feature recrystallization, and yielding a distribution of grain sizes with gaps between most of their surface area characterized by reentrant angles which effectively trap light due to optical dielectric contrast between the absorber and the gaps.

CIGS surfaces that are rough on length scales comparable to the wavelengths of incident optical solar radiation will scatter light especially strongly, reducing reflection and increasing the effective path length of photons which enter into the absorber volume thereby increasing their probability of absorption. Such light trapping surface structures and film morphologies are also effective in trapping photons internally generated by radiative recombination (sometimes referred to as photon recycling). This permits the use of less volumetric CIGS semiconductor material per unit area while still absorbing substantially all of the incident solar radiation, reducing cost both through direct materials savings and improved throughput of the semiconductor deposition tools. If the semiconductor material's electronic bulk and surface recombination properties are good, this can simultaneously increase photovoltage, photocurrent and fill factor, resulting in higher conversion efficiency than can be obtained using conventional planar CIGS absorbers containing the same volume of CIGS.

The morphological asymmetries (e.g. voids and/or pores) do not extend all the way through the film. This means that the absorber film is in substantial continuous contact with a back contract; and there is little to no chance of a short circuit from conformally deposited buffer and/or emitter films and/or layers.

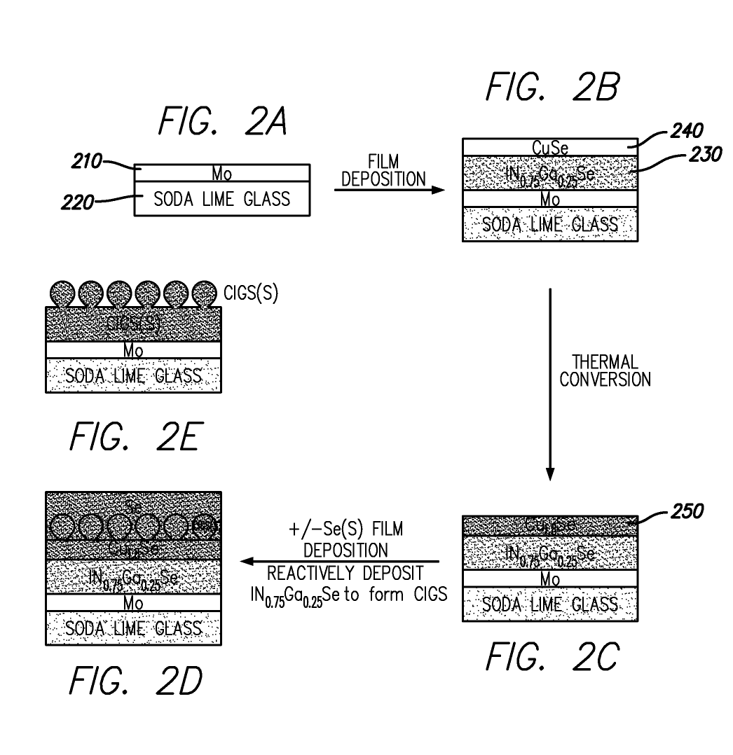

Referring to FIGS. 2A-2E, the method of reacting three or more odd numbers of precursor layers as described in the following steps can be optimized to create novel and unprecedented semiconductor layer morphologies in CIGS with efficient, nearly lambertian scattering properties at optical wavelengths characteristic of the solar spectrum combined with device-quality am bipolar carrier transport properties and low rates of non-radiative recombination.

Referring to FIG. 2A, a substrate can include a layer of Mo 210 coupled to soda lime glass 220. Referring to FIG. 2B, a layer 230 of phase-pure (In_{1-y}Ga_{y})₂Se₃ (y can be from 0 to 1 and variable through its thickness) is deposited at a temperature lower than 375° C.

A CuSe layer 240 deposition follows at a temperature below 275° C. Thus, the layer of phase-pure (In_{1-y}Ga_{y})₂Se₃ Is maintained intact, with relatively little interfacial reaction compared to higher temperature deposition.

CuSe film deposition is done without the need for precise control of the Se to metal flux ratio, and the ratio of (In_{1-y}Ga_{y})₂Se₃ to CuSe film thicknesses can be adjusted to achieve the desired final material composition depth profile.

Referring to FIG. 2C, the precursor layers are then heated to a temperature above 275° C. to partially convert the surface CuSe material into a mixture of CuSe and Cu₂₋ₓSe (0.2=<X<1) material 250.

The foregoing steps can be done one time or repeated multiple times for multiple precursor layer pairs.

Referring to FIG. 2D, the deposition of these multi-layer precursor pairs is followed by the deposition of (In_{1-y}Ga_{y})₂Se₃ at a temperature greater than 325° C. for sufficient time to react this layer with the underlying Cu₂₋ₓSe (0.2=<X<1) and/or CuSe layer in the presence of excess Se vapor and convert all of the IGS into a CIGS reaction product at the surface. Characteristic morphological asymmetries are created in a surface portion of the final structure by simultaneous process of Cu—Se flux-assisted re-crystallization characterized by coalescence and coarsening of both the CIGS grains and the voids formed between them by reactive mass transport.

The resulting structure from the preceding step can be optionally coated with elemental selenium or selenium-sulfur mixtures to ensure high chalcogen activity during subsequent thermal processing to achieve this coalescence and coarsening. This coating can be termed a thin film cap layer.

Referring to FIG. 2E, the completed precursor structure is ramped to a temperature greater than 375° C. and preferably more than 500° C. under conditions of high selenium and/or sulfur chemical activity for sufficient time to completely react all of the (In_{1-y}Ga_{y})₂Se₃ and Cu₂₋ₓSe (0.2=<X<1) layers leaving only the CIGS reaction product. These conditions create a high reactive diffusion flux of copper and selenium favorable to crystal grain regrowth and coalescence, recyrstallizing dendritic structures formed in preceding lower temperature reaction steps, and yielding a distribution of grain sizes with gaps between most of their surface area characterized by reentrant angles which effectively trap light. The ramping can include rapid optical processing (also known as selective rapid thermal processing) and/or rapid isothermal processing.

Examples of Se or Se+S supply during reaction include a stoichiometric excess of Se in the overall precursor mixture composition, the thin film cap layer on top of multi-layer precursor and/or independently controlled Se and optionally S vapor sources directly integrated to the second-stage CIGS reaction tool.

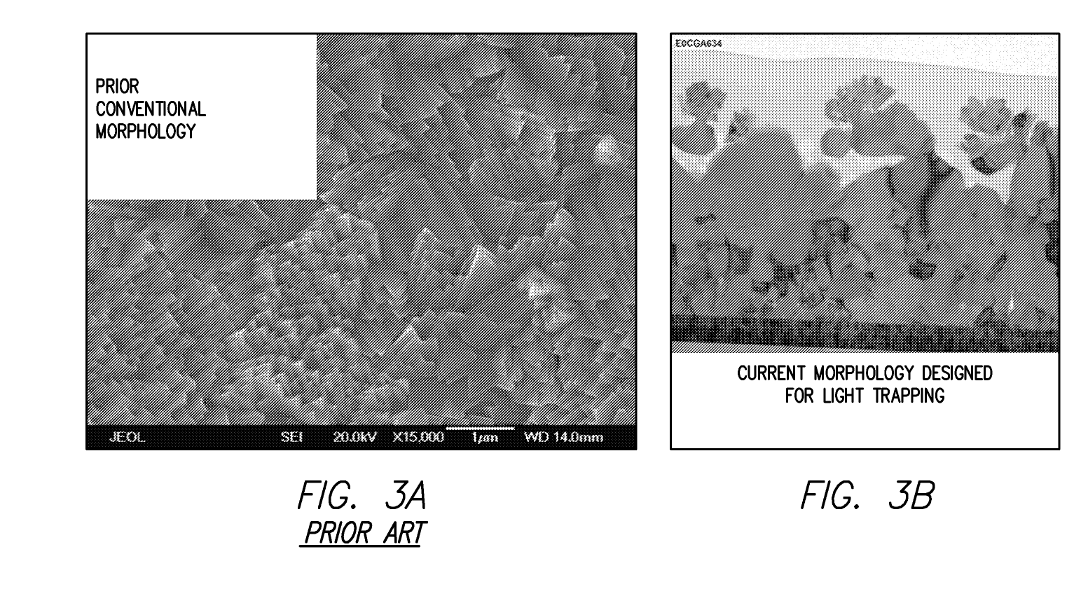

Embodiments of the present disclosure can include self-assembled nanostructure formation for light trapping. Referring to FIG. 3A, a conventional CIGS absorber morphology is shown for comparison purposes. FIG. 3B, shows an embodiment of the present disclosure with a morphology designed for light trapping. Embodiments of the present disclosure can include a precursor deposition process that has been optimized to facilitate formation of nanoscale morphological asymmetries in the final structure by Cu—Se flux-assisted re-crystallization characterized by coalescence and coarsening of both the CIGS grains and the voids formed between them by reactive mass transport.

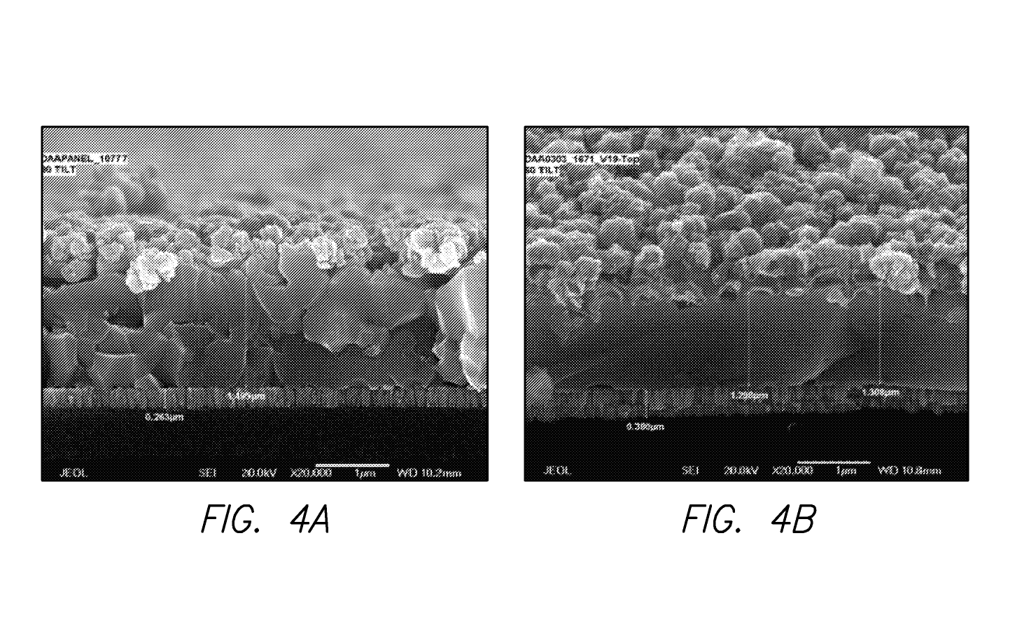

Embodiments of the present disclosure can include at least two approaches to ultrafast heating that both show improved crystallization. Referring to FIG. 4A, a rapid isothermal processor (RIP) approach can involve a 6 minute process time. Referring to FIG. 4B, a rapid optical processor (ROP) approach can involve a 1 minute process time. The results shown in FIGS. 4A-4B prove the unique surface morphology does not require a slow reaction rate in the second stage, but is the signature of nanoscale nucleation of CIGS in deposition of the final precursor layer at relatively low temperature.

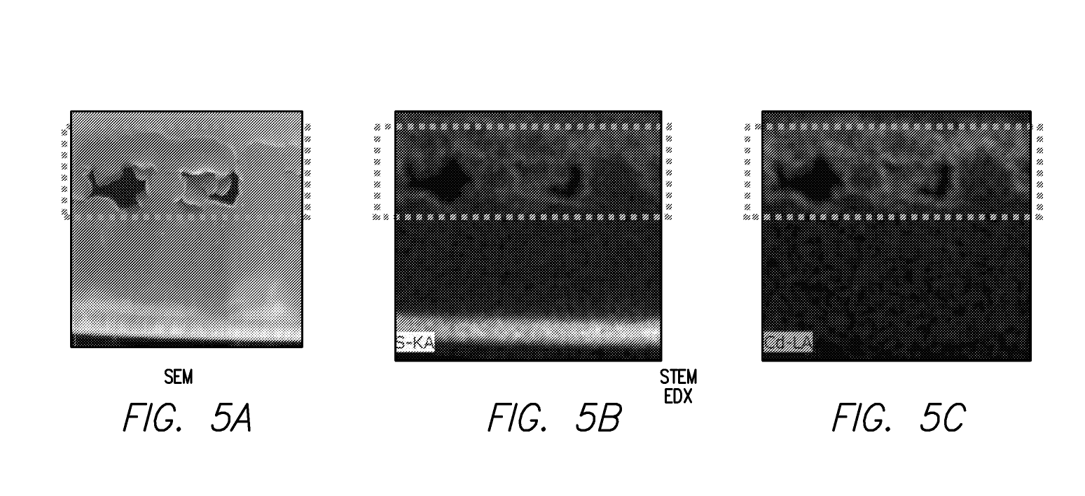

Referring to FIGS. 5A-5C, embodiments of the present disclosure can include a buffer layer conformally coupled a CIGS absorber layer designed for light trapping. Chemical bath deposition (CBD) can be used for depositing the buffer layer conformally so that it contact the complex light-trapping nanostructure surface of the GIGS absorber layer that is designed for light trapping.

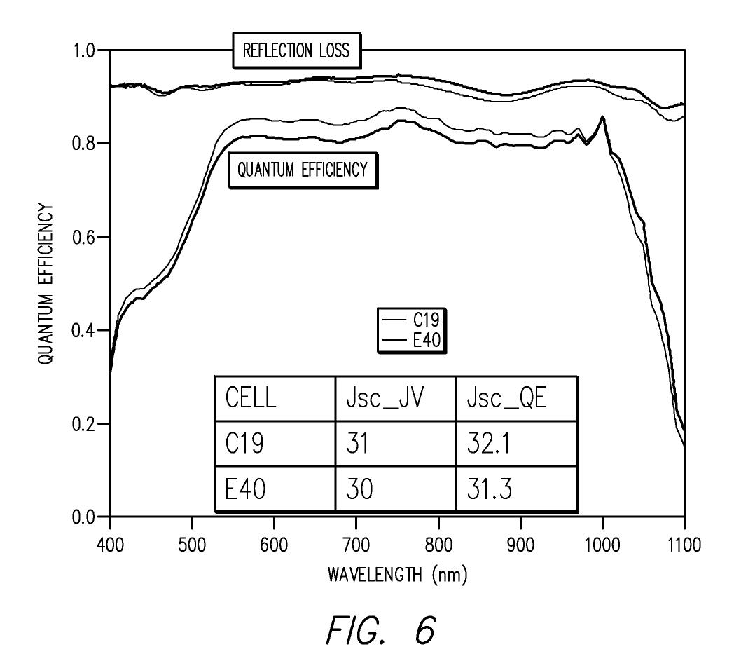

FIG. 6 shows quantum efficiency as a function of wavelength (nm) for a GIGS absorber layer designed for light trapping conformally coupled to a buffer layer. The exceptional IR response indicates long effective path length. The reflection/quantum efficiency gap shows significant current loss with sputtered transparent resistive oxide (TRO).

Incorporating conformal junction-forming and collection layers (e.g. buffer and slightly conductive transparent oxide layer) onto the nanostructured CIGS surface alters the built-in potential distribution within the nanostructures, allowing minority carrier extraction from the GIGS through the nearest surface. This significantly reduces the average path length for carriers generated within the CIGS to the junction, dramatically reducing their recombination probability and thereby increasing both photocurrent and photovoltage.

Still referring to FIG. 6, this is a graph of the wavelength dependence of both reflection and the fraction of photons collected as electrons (QE), and this data is for two different devices, both with sputtered (non-conformal) ZnO TRO. There's a gap between the reflection loss line and the quantum efficiency. That gap shows how much of the absorbed light does not end up generating electrons, and thus represents a ˜8-10% loss of photocurrent. The table immediately below relates to FIG. 8 and shows Jsc_JV and Jsc_QE for cells C19 and E40, where Jsc_QE is the result of convolving the spectral solar spectrum with the QE measurement and Jsc_JV is the measured current under a simulated AM1.5G spectrum.

| Cell | Jsc_JV | Jsc_QE |
|---|---|---|
| C19 | 31 | 32.1 |
| E40 | 30 | 31.3 |

| | Intrinsic | | Eff | Voc | Jsc | FF | Rs | Gsh |
|---|---|---|---|---|---|---|---|---|
| Deposition type | layer | Type | % | (mV) | (mA/cm²) | % | (ohms) | (S) |
| Sputtering [nonconformal] | ZnO | AVG | 10.3 | 583 | 30.7 | 58.4 | 5.9 | 0.001 |
| | | Champ | 10.6 | 586 | 30.9 | 58.4 | 6.5 | 0.0002 |
| Atomic Layer Deposition | ZnO | Avg | 13.5 | 598 | 34.1 | 66.6 | 2.9 | 0.0008 |
| (ALD) [conformal] | | Champ | 13.9 | 602 | 34.5 | 67 | 3.4 | 0.0007 |

The tables show a comparison of the current-voltage properties of nanostructured CIGS devices, all with conformal CBD CdS buffer (junction-forming) layers, but with the next layer of the emitter structure (ZnO Transparent Resistive Oxide, which is not doped to be highly conductive, but is nevertheless slightly conductive) deposited by two different methods. The measured photocurrent (Jsc) of the sputtered device is the same as the current measured in the same type of devices shown in the picture: 30-31 mA/cm2. The current measured for the device with the conformal ALD ZnO TRO layer is >34 mA/cm2, which is 8-10% higher. Thus the conformal coating of junction-forming buffer and current-carrying TRO layers eliminates the loss of photocurrent observed with non-conformal conducting layers in contact with the junction forming partner to the CIGS absorber.

This is the dramatic effect of 3-dimensional carrier collection in nanostructured CIGS absorbers, which is effective so long as the conformal junction does not short to the molybdenum back contact through voids in the GIGS covering the molybdenum layer.

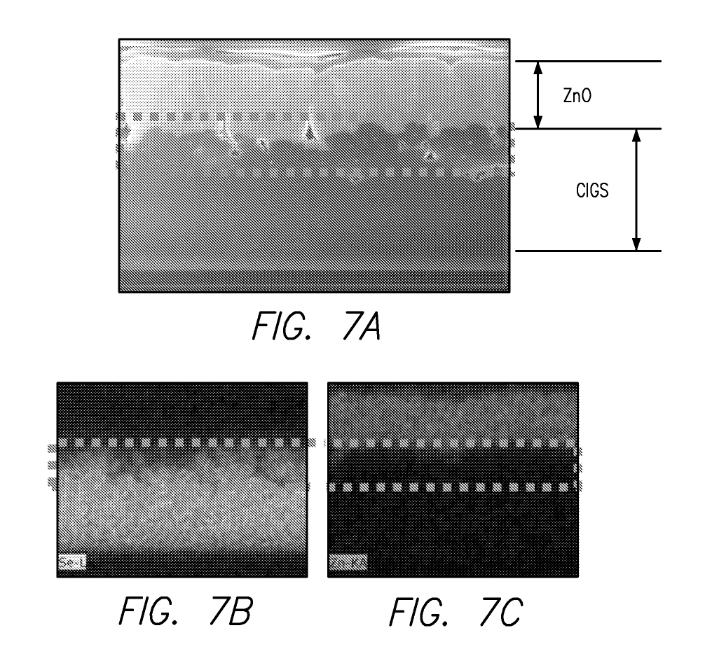

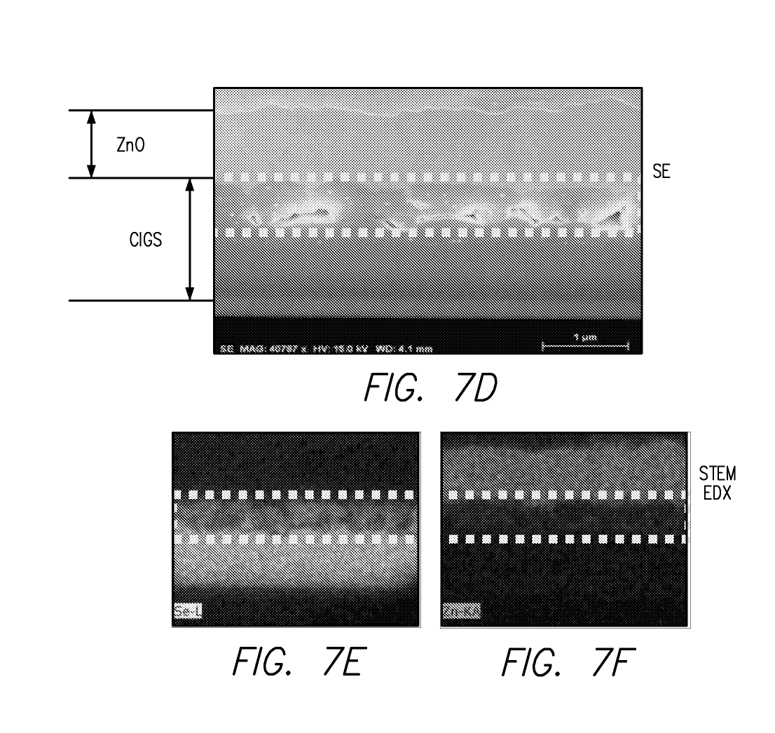

Referring to FIGS. 7A-7F, a comparison of two method for deposition a ZnO transparent resistive oxide layer can be appreciated. FIGS. 7A-7C show the results of sputtering a ZnO transparent resistive oxide layer on a buffer layer coupled to a CIGS absorber layer that is designed for light trapping. Sputtering fails to contact the complex light-trapping nanostructured surface. FIGS. 7D-7F show the results of atomic layer deposition (ALE)) of a ZnO transparent resistive oxide layer on a buffer layer coupled to a GIGS absorber layer designed for light trapping. The use of atomic layer deposition conformally contacts the complex light-trapping nanostructured surface.

### DEFINITIONS

The term compound is intended to mean a substance formed when two or more chemical elements are chemically bonded together, the elements present in ratios with a limited range of variation and characteristic crystal structure. The term phase is intended to mean a limited range of compositions of a mixture of the elements (in a thermochemical system) throughout which the chemical potential of the mixture varies with composition, and which either changes discontinuously or remains constant outside of that range. The phrase cation content is intended to mean the percentage or relative amount of a given cation of interest (relative to total cations) in a given volume or mass of interest. The term absorber is intended to mean the photon absorbing portion of a photovoltaic. The term buffer is intended to mean the junction forming region of a photovoltaic. The term emitter is intended to mean the negative contact of an illuminated photovoltaic without current flow. The term transparent resistive oxide (TRO) (sometimes called a slightly conductive transparent oxide) is intended to mean a substantially photon transparent, electronically resistive portion of a photovoltaic that is not intentionally doped, but may be conductive. The term amorphous transparent conductive layer is intended to mean a non-crystalline, substantially photon transparent, electronically conducting portion of a photovoltaic. The term back contact is intended to mean the contact of a photovoltaic on the side opposite the incident illumination. The term photovoltaic is intended to mean an article of manufacture for the generation of a voltage when radiant energy falls on the boundary between dissimilar substances (as two different semiconductors). The term light is intended to mean frequencies greater than or equal to approximately 300 GHz as well as the microwave spectrum.

The term uniformly is intended to mean unvarying or deviate very little from a given and/or expected value (e.g. within 10% of). The term substantially is intended to mean largely but not necessarily wholly that which is specified. The term approximately is intended to mean at least close to a given value (e.g., within 10% of). The term generally is intended to mean at least approaching a given state. The term coupled is intended to mean connected, although not necessarily directly, and not necessarily mechanically.

The terms first or one, and the phrases at least a first or at least one, are intended to mean the singular or the plural unless it is clear from the intrinsic text of this document that it is meant otherwise. The terms second or another, and the phrases at least a second or at least another, are intended to mean the singular or the plural unless it is clear from the intrinsic text of this document that it is meant otherwise. Unless expressly stated to the contrary in the intrinsic text of this document, the term or is intended to mean an inclusive or and not an exclusive or. Specifically, a condition A or B is satisfied by any one of the following: A is true (or present) and B is false (or not present), A is false (or not present) and B is true (or present), and both A and B are true (or present). The terms a and/or an are employed for grammatical style and merely for convenience.

The term plurality is intended to mean two or more than two. The term any is intended to mean all applicable members of a set or at least a subset of all applicable members of the set. The term means, when followed by the term “for” is intended to mean hardware, firmware and/or software for achieving a result. The term step, when followed by the term “for” is intended to mean a (sub)method, (sub)process and/or (sub)routine for achieving the recited result. Unless otherwise defined, all technical and scientific terms used herein have the same meaning as commonly understood by one of ordinary skill in the art to which this present disclosure belongs. In case of conflict, the present specification, including definitions, will control.

The described embodiments and examples are illustrative only and not intended to be limiting. Although embodiments of the present disclosure can be implemented separately, embodiments of the present disclosure may be integrated into the system(s) with which they are associated. All the embodiments of the present disclosure disclosed herein can be made and used without undue experimentation in light of the disclosure. Embodiments of the present disclosure are not limited by theoretical statements (if any) recited herein. The individual steps of embodiments of the present disclosure need not be performed in the disclosed manner, or combined in the disclosed sequences, but may be performed in any and all manner and/or combined in any and all sequences. The individual components of embodiments of the present disclosure need not be formed in the disclosed shapes, or combined in the disclosed configurations, but could be provided in any and all shapes, and/or combined in any and all configurations. The individual components need not be fabricated from the disclosed materials, but could be fabricated from any and all suitable materials. Homologous replacements may be substituted for the substances described herein.

Various substitutions, modifications, additions and/or rearrangements of the features of embodiments of the present disclosure may be made without deviating from the scope of the underlying inventive concept. All the disclosed elements and features of each disclosed embodiment can be combined with, or substituted for, the disclosed elements and features of every other disclosed embodiment except where such elements or features are mutually exclusive. The scope of the underlying inventive concept as defined by the appended claims and their equivalents cover all such substitutions, modifications, additions and/or rearrangements.

The appended claims are not to be interpreted as including means-plus-function limitations, unless such a limitation is explicitly recited in a given claim using the phrase(s) “means for” “mechanism for and/or “step for”. Subgeneric embodiments of” the invention are delineated by the appended independent claims and their equivalents. Specific embodiments of the invention are differentiated by the appended dependent claims and their equivalents.

What is claimed is:

1. A method, comprising:
fabricating a layered precursor including:
depositing a first film including a first indium gallium selenide compound on a substrate; then
depositing a second film including a CuSe compound; then
heating the substrate, the first film and the second film to convert the CuSe compound in the second film to a Cu₂₋ₓSe (0.2=<x<1) compound; then
reactively depositing a third film including a second indium gallium selenide compound to convert the first film, the second film and the third film into a CIGS absorber film; and
forming nanoscale morphological asymmetries in the CIGS absorber film,
wherein a surface portion of the CIGS absorber film has a distribution of grain sizes with gaps between most of their surface area characterized by reentrant angles which effectively trap light.

2. The method of claim 1, wherein forming nanoscale morphological asymmetries in the CIGS absorber film includes Cu—Se flux-assisted re-crystallization.

3. The method of claim 2, wherein Cu—Se flux-assisted re-crystallization includes coalescence and coarsening of both CIGS grains and voids formed there between by reactive mass transport.

4. The method of claim 1, wherein forming includes rapid optical processing.

5. The method of claim 1, wherein forming includes rapid isothermal processing.

6. The method of claim 1, further comprising depositing a cap film on the third film, the cap film including Se.

7. The method of claim 6, wherein the cap film includes Se₁₋ₛSₛ with optional Na, where 0≦s≦1.

8. The method of claim 1, further comprising depositing a buffer film on the CIGS absorber film.

9. The method of claim 8, wherein depositing the buffer film includes at least one member selected from the group consisting of chemical bath deposition and atomic layer deposition.

10. The method of claim 8, further comprising depositing a transparent resistive oxide on the buffer film.

11. The method of claim 10, wherein depositing the transparent resistive oxide includes at least one member selected from the group consisting of chemical bath deposition and atomic layer deposition.

12. A composition of matter, comprising a GIGS absorber film including nanoscale morphological asymmetries in the CIGS absorber film, wherein a surface portion of the CIGS absorber film has a distribution of grain sizes with gaps between most of their surface area characterized by reentrant angles which effectively trap light.

13. The composition of matter of claim 12, further comprising a buffer film coupled to the GIGS absorber film.

14. The composition of matter of claim 12, further comprising a transparent resistive oxide coupled to the buffer film.

15. An apparatus, comprising a CIGS absorber film including nanoscale morphological asymmetries in the CIGS absorber film, wherein a surface portion of the CIGS absorber film has a distribution of grain sizes with gaps between most of their surface area characterized by reentrant angles which effectively trap light.

16. The apparatus of claim 15, further comprising a buffer film coupled to the CIGS absorber film.

17. The apparatus of claim 16, further comprising a transparent resistive oxide coupled to the buffer film.

18. The apparatus of claim 17, wherein the transparent resistive oxide include amorphous zinc tin oxide.

19. A solar cell module, comprising the apparatus of claim 15.
